(19) United States
(12) Patent Application Publication
(10) Pub. No.: US 2004/0179702 A1
(43) Pub. Date: Sep. 16, 2004

(54) Transducer assembly with modifiable buffer circuit and method for adjusting thereof

(76) Inventor: Steven E. Boor, Plano, TX (US)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/797,804

(22) Filed: Mar. 10, 2004

Related U.S. Application Data
(60) Provisional application No. 60/453,645, filed on Mar. 11, 2003.

(51) Int. Cl. H04R 3/00; H03F 21/00

(52) U.S. Cl. 381/111; 381/116

(57) ABSTRACT

A method and system for adjusting the frequency response characteristics of a transducer assembly (312) is disclosed. The transducer assembly (312) includes a modifiable buffer circuit (100) being generally enclosed within a housing (314). Electrical signal connections for modifying the operating state of the modifiable buffer circuit (100) are accessible outside the housing (314). The modifiable buffer circuit (100) further includes a plurality of signal inputs (234) and outputs (230), the plurality of signal inputs (234) are accessible from outside the housing. A predetermined relationship exists between the plurality of signal inputs (234) and the plurality of outputs (230). A resistor network (224) is operably connected to the plurality of outputs (230) wherein a portion of the resistor network (224) is operably disconnected from a filter network (218) in response to the plurality of signal inputs (234).

### CROSS REFERENCE

This application claims the benefit of U.S. Provisional Patent Application No. 60/453,645, filed Mar. 11, 2003, the disclosure of which is hereby incorporated herein by reference in its entirety for all purposes.

### TECHNICAL FIELD

This patent generally relates to microphone applications. More specifically, this patent describes a system and method for modifying the operational characteristics of a miniature microphone subsequent to its placement within a sealed housing.

### BACKGROUND

Today's assisted-listening devices, e.g., hearing aids, offer features that significantly enhance the ability of a hearing impaired individual to listen effectively in a wide variety of environments. One recent and popular feature is the utilization of multiple microphones within the hearing aid shell to provide listening directionality, which is highly effective in filtering out undesirable background noise. However, it has been a non-trivial task for transducer manufacturers to produce miniature microphone assemblies having the matched acoustical properties needed for creating stable and predictable directional hearing aid responses. Extensive and costly testing and procedures are required at the end of the microphone manufacturing process to provide acoustically matched microphones to hearing aid manufacturers. These procedures become more involved and costly as the number of matched microphones in a matched set is increased.

The acoustical properties of each microphone assembly are highly dependent on a few controlling factors and its final “assembled geometry.” For example, variability in acoustic sensitivity occurs due to variation in the size of the top and bottom cups of the microphone assembly's housing (which set the nominal acoustic front and back volumes, respectively) and the amount of epoxy used to acoustically seal the gaps between the cups. The use of a temporary top cover is not practical for making mechanical, geometrical, or electrical adjustments to a microphone assembly in a manufacturing environment because of the potential for acoustic leaks during adjustment. Furthermore, a temporary cover cannot account for the variability in the final size of the top cup and the actual amount of epoxy used to seal the assembly.

Many manufacturing and R&D studies have shown potential manufacturing advantages in utilizing a post-assembly adjustment process to produce microphones having closely matched acoustical properties.

The accompanying figures, where like reference numerals refer to identical or functionally similar elements throughout the separate views and which together with the detailed description below are incorporated in and form part of the specification, serve to further illustrate various embodiments and to explain various principles and advantages, all in accordance with the present invention.

### BRIEF DESCRIPTION OF THE DRAWINGS

FIG. 1 is a block diagram of a modifiable buffer circuit;

FIG. 2 is a schematic diagram of one portion of the modifiable buffer circuit;

FIG. 3 is a schematic diagram of another portion of the modifiable buffer circuit;

FIG. 4 is a schematic diagram of another portion of the modifiable buffer circuit;

FIG. 5 depicts an assembled microphone assembly prior to adjustment of its operational characteristics; and,

FIG. 6 depicts an assembled microphone assembly subsequent to adjustment of its operational characteristics.

### DETAILED DESCRIPTION

While the invention is susceptible to embodiments in many different forms, there are shown in the drawings and will herein be described in detail, embodiments of the invention with the understanding that the present disclosures are to be considered as exemplifications of the principles of the invention and are not intended to limit the broad aspects of the invention to the embodiments illustrated.

One aspect for post-assembly adjustment of the frequency response of a miniature microphone assembly includes introducing minor shifts in the gain and/or phase characteristics of its inherent electronics. Trimming circuitry incorporated within the modifiable buffer circuit allows small adjustments in the gain and/or phase of the input to output transfer function of the circuit. Thus, the overall frequency response of each microphone assembly is capable of being brought to within a much narrower tolerance window desirable for a matched set of microphones. It is possible with this post-assembly adjustment technique that an entire production batch of microphone assemblies could be manufactured within very tight acoustical tolerances, eliminating the need for the costly sorting of matched units. Providing a larger batch of matched microphone assemblies would enable the hearing aid manufacturer to produce highly directional hearing aids that could utilize three, four, or even more matched microphones within each assisted listening device.

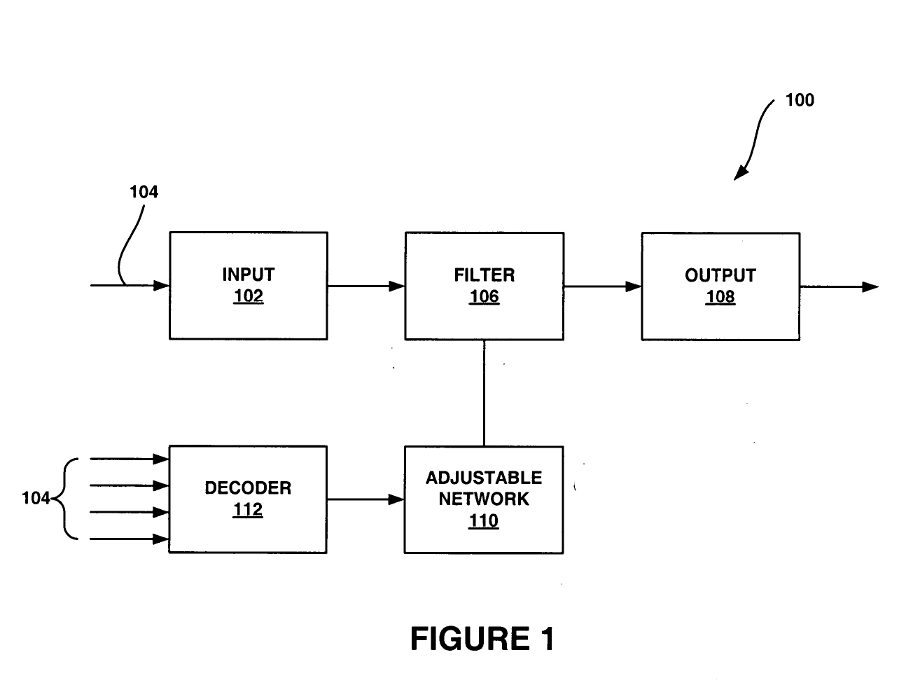

Referring to FIG. 1, a block diagram of a modifiable buffer circuit is discussed and described. The modifiable buffer circuit 100 has an input circuit 102 with an input 104 for receiving a signal from a source (not depicted), such as a microphone. The input 102 provides overload protection and a high impedance to the signal source. A filter 106 is coupled to the input circuit 102. The filter 106 is coupled to an output circuit 108 for driving and impedance matching a subsequent component. The filter 106 is able to shape the profile of the signal for phase and frequency response. To better match the overall characteristics of an acoustically sealed transducer assembly 312 to other similar assemblies, an adjustable network 110 provides a mechanism to adjust the signal profile to compensate for expected variations due to component tolerances and assembly differences. A decoder 112 with a plurality of inputs 114 can be used to control the adjustable network 110.

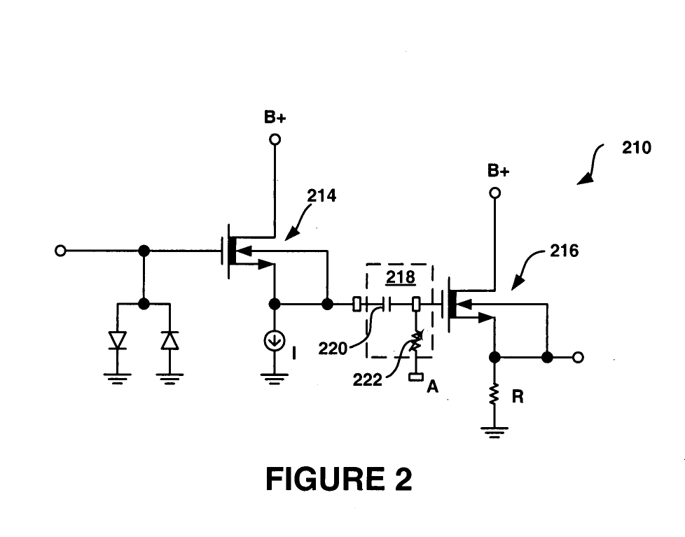

One possible modifiable buffer circuit implementation for an “in-the-can” post-assembly adjustment method is shown in FIGS. 2, 3, and 4. Note that the schematic diagrams are used to primarily illustrate an example of how a frequency response adjustment, e.g., low frequency phase, of a finished microphone assembly can be accomplished, with up to 4 bits of trim control. Adjustment of the filter network's RC time-constant provides an electrical means for tightly controlling the overall low frequency phase response of the microphone assembly, which is a performance characteristic needed from matched microphones in directional hearing aid systems.

Referring to FIG. 2, a modifiable buffer circuit 210 for the transducer assembly 312 may include a first 214 and second 216 impedance buffer and a filter network 218, for coupling to a transducer (not depicted). The filter network 218 shown within the dotted portion of FIG. 2 functions as a high-pass filter network and includes a capacitive element 220 and a resistive element 222. The resistive element 222 may be a hybrid resistor trimmed to a nominal value, e.g., 500 Kohms, a resistor network 224, or a combination thereof. The capacitive element 220 could be included along with other electronic components on a modifiable buffer circuit, incorporated directly into a hybrid circuit, or added as a stand-alone miniature chip component.

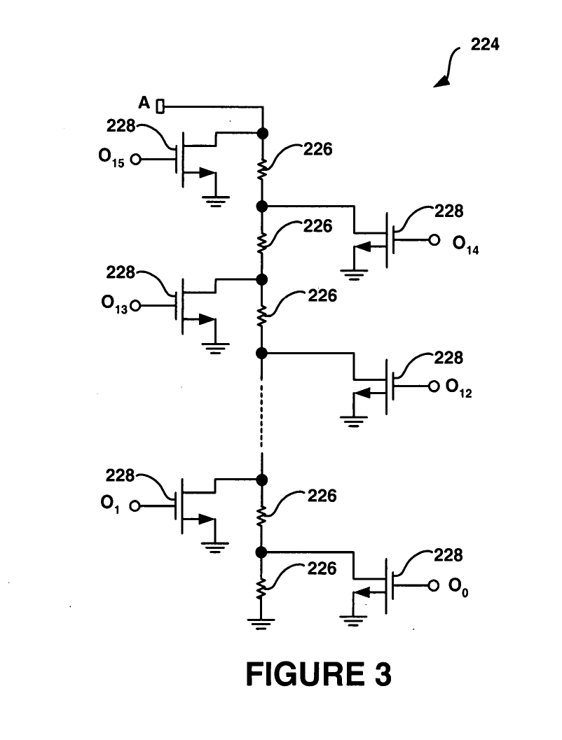

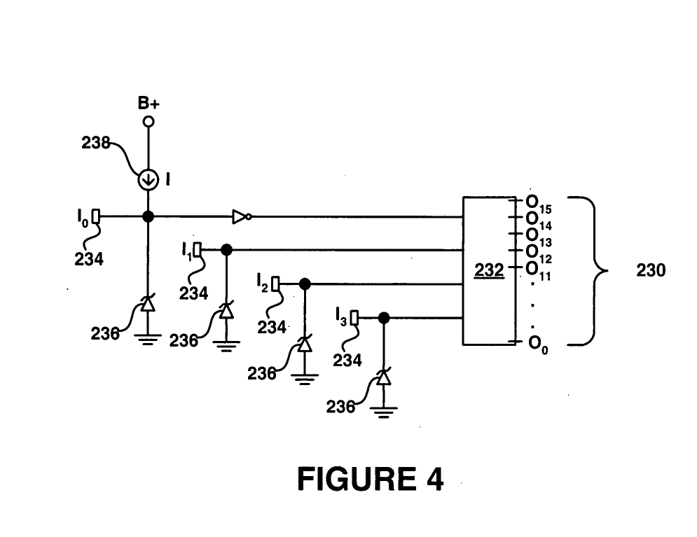

In an embodiment including the resistor network 224, as shown in FIG. 3, a plurality of resistors 226 are operably connected to a plurality of switches 228. The circuitry depicted in FIGS. 2 and 3 are operably connected at node A. Each switch 228 is operably connected to an output 230 of a controller 232, shown in FIG. 4. The controller 232 includes a plurality of inputs 234. A plurality of biasing elements 236 are operably connected between the inputs 234 and ground. The biasing element 236 may be a “Zener zap” diode. The biasing element 236, in combination with an input signal received at the controller 232, cooperate to determine an output signal to the resistor network 224, which essentially dictates, in an exemplary embodiment, the amount of resistance to be removed from connection with the filter network 218, thus adjusting the filter's RC time constant and phase characteristics. The current source 238 coupled to the biasing element 236 on the first input 234 provides a bias potential and is normally repeated for each input 234, but is not depicted to simplify the drawing.

A relationship exists between the inputs 234 and the outputs 230 such that selection of one or more inputs 234 correlates to one output 230. In the embodiment shown in FIG. 4, the controller 232 functions similarly to a decoder wherein each of sixteen input combinations results in an exclusive output. In response to a given set of input conditions provided to the controller 232, a specific output results and is utilized to modify the amount of resistance that will be operably connected to the capacitor 220 of the filter network 218. In the resistor network 224 shown in FIG. 3, each of the plurality of resistors 226 is serially connected between the filter network 218 and ground. Each output 230 of the controller 232 is operably connected to one of the switches 228 and one of the plurality of resistors 226. Selection of a specified output 230 will adjust the amount of resistance operably connected to the capacitor 220 of the filter network 218 by shunting a corresponding portion of the resistive network 224 to ground. The switches 228 can be transistors, FETs, or any other electrical device capable of similar switching functionality and known to one of ordinary skill in the art.

Other configurations of the transducer assembly 312 are contemplated wherein the transducer may be operable to generate acoustic energy as well as receive it, that is, the transducer may be either a speaker or a microphone.

Other configurations of the filter network 218 are easily understood by one of ordinary skill in the art in order to accomplish specific phase and frequency response characteristics. For example, a multiple pole filter could be incorporated using multiple resistor networks 224 (discussed below) to allow further flexibility in adjustment and matching. Capacitive or inductive networks could be used in place of or in conjunction with the resistor networks 224. One of ordinary skill in the art will understand that other embodiments for configuring the resistor network 224, for example, a parallel network, can be developed wherein the adjustment is made by deactivating one or more of the switches 228.

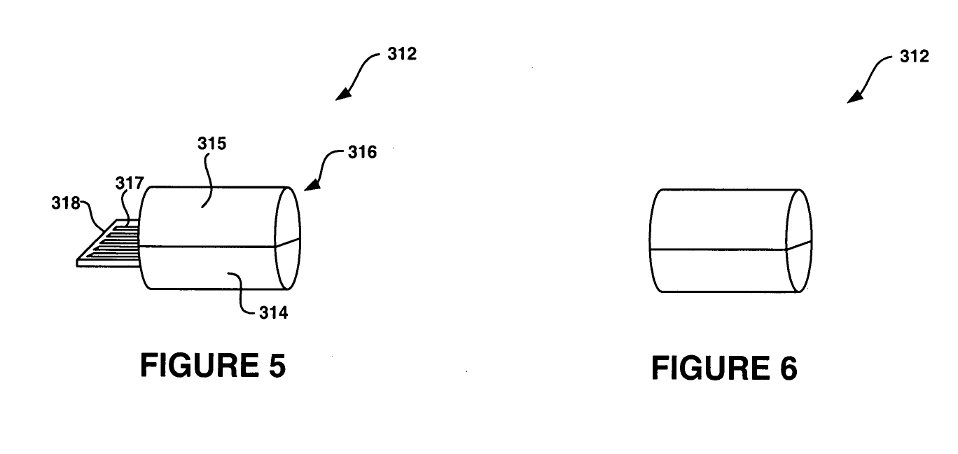

Referring to FIGS. 5 and 6, a transducer assembly 312 includes a modifiable buffer circuit 100 enclosed within a housing 316. Typically, modifiable buffer circuit 100 and a microphone (not depicted) are acoustically sealed within the housing 316 formed by sealing cup-shaped top 315 and bottom 314 portions. An access port 320 in the housing 316 is internally sealed by the transducer. One of the housing portions 314, 315 may have an accommodation for receiving the substrate carrying the modifiable buffer circuit 100, such as standoffs or posts. Electrical signal connections 317 to the modifiable buffer circuit 100 extend outside the sealed transducer assembly 312, as shown in FIG. 5. The plurality of inputs 234 are accessible via the electrical signal connections 317 via a removable portion 318 of the modifiable buffer circuit extending from the transducer assembly 312. A notch or slot in one or both of the housing portions 314, 315 may be formed to allow the removable portion 318 to extend through the housing 316 with a close enough fit to enable acoustically sealing around the buffer circuit. The seal may be further enhanced with a sealer such as epoxy. The operational characteristics, e.g., frequency response, of the transducer assembly 312 can be analyzed to determine a response characteristic of the buffer circuit 100. This response characteristic can be compared to a desired response characteristic and the comparison used to determine an adjustment for reducing the difference between the actual and desired responses. Given the impact of both circuit component tolerances and assembly differences, the adjustments to the resistor network 224 may have to be empirically determined, but are easily comprehended by one of ordinary skill.

Depending on the analysis and the operating frequency response desired for the specific transducer assembly 312, the operational characteristics of the transducer assembly 312 can be adjusted by providing inputs to the external signal connections 317 of the modifiable buffer circuit 100. If an adjustment is required, a specific switch 228 will be utilized in response to an input signal received at the controller 232 to modify the amount of resistance provided by the resistor network 224. After the desired operational frequency response is obtained, the external signal connections 317 on the removable portion 318 extending out of the transducer assembly 312 can be removed, as shown in FIG. 6. This effectively locks the modifiable buffer circuit 100 in a final configuration, both electrically and physically, leaving the transducer assembly 312 in a final form factor with the external signal connections 317 no longer accessible.

Ultra-low cost hybrid thick-film circuit technology can provide as many external signal connections 317 as required to allow the desired level of adjustment, for example, in one embodiment four external signal connections 317 can extend out of the transducer assembly 312. A thick film circuit on ceramic or FR4 can be scored to provide an area of weakness for removing the removable contact 318 portion. In this embodiment, the signal inputs 234 may allow the acoustic variability between modifiable buffer circuits to be tightened by a factor of approximately ten.

Several trim mechanisms are possible for post-assembly adjustment of microphone characteristics: polysilicon fuses, “Zener zap” diodes, EEPROM, or laser trimmable hybrid resistors.

Polysilicon (poly) fuses require a nitride passivation opening on the IC surface and exposure to air for the vaporized material to be ejected properly from the circuit during adjustment, and therefore may not be conducive to being used when the circuit is encapsulated by epoxy and within a limited air volume as they are on standard hybrid circuits inside of are microphone. Thus, poly fuses are not commonly used for use in the post-assembly adjustment of microphones.

EEPROM circuitry has the advantage of allowing electronic adjustment at any time during the lifetime of the product, and also provides the distinct advantage of allowing multiplexing methods with existing microphone terminals to reprogram the microphone characteristics. Nonetheless, EEPROM may require extra wafer processing technology complexity and substantial control circuit area overhead—both of which, given the current state of the art, may add to the cost of the end product.

“Zener zap” diodes are an easily accommodated and cost-effective trim element for use in an “in-the-can” trimmable microphone buffer circuit because they operate as anti-fuses via short-circuit action and circumvent the above problems inherent with polysilicon fuses. In contrast to EEPROM, each “Zener zap” component is limited to a one-time only adjustment of the microphone assembly characteristics, but has the advantages of being compatible with standard BiCMOS process technology and requiring a minimum amount of support circuitry.

Laser trimmable hybrid resistors could also be utilized as part of the electronically adjustable circuitry. This type of component would have to be accessible via an optical window through the microphone case, or else would be required to be an exposed component outside of the microphone case. It is unlikely, given the current state of the art, that a laser trimmable resistor configuration would have significant advantages over other described alternatives.

In spite of the deficiencies of the alternative technologies listed above, each are adaptable to be used with the described embodiments of the invention and are contemplated as being within the scope of the claimed invention.

The circuit elements described above are commodity electrical components and are readily available from any number of commercial electronics distributors. Thick film hybrid circuits and a variety of suitable substrate materials, including ceramics, are well known and have been in commercial use for well over 20 years.

It will be understood that the invention may be embodied in other specific forms departing from the spirit or central characteristics thereof. The present embodiment, therefore, is to be considered in all respects as illustrative and not restrictive, and the invention is not to be limited to the details given herein.

What is claimed is:

1. A transducer assembly comprising:
a housing having an acoustic seal;
a transducer for coupling acoustic energy between an outside of the housing and an inside of the housing; and
a hybrid circuit partially enclosed within the housing, the hybrid circuit comprising:
a first input circuit for coupling a signal from the transducer;
a filter network coupled to the first input circuit;
an output circuit coupled to the filter network;
a tuner for adjusting the filter network; and
a controller for altering a value of the tuner, the controller having a second input on a portion of the hybrid circuit external to the housing,
whereby a tuning signal coupled to the second input is used to adjust the tuner, thereby changing a characteristic of the filter network.

2. The transducer assembly of claim 1 wherein the controller retains a setting upon receiving the tuning signal.

3. The transducer assembly of claim 1 wherein the portion of the hybrid circuit external to the housing is permanently removed after the controller receives the tuning signal.

4. The transducer assembly of claim 1 wherein the tuner is a ladder network, the ladder network adjustable by activating or deactivating a semiconductor device between an element of the ladder network and a signal ground connection.

5. The transducer assembly of claim 4 wherein the ladder network comprises resistors.

6. The transducer assembly of claim 5 wherein the resistors have a nominal value of 5.5 k ohms.

7. The transducer assembly of claim 4 wherein the ladder network comprises capacitors.

8. The transducer assembly of claim 4 wherein the semiconductor device is a field effect transistor (FET).

9. The transducer assembly of claim 1 wherein the second input is coupled to a biasing element, the biasing element maintaining a state after receiving the tuning signal.

10. The transducer assembly of claim 1 wherein the transducer is a microphone.

11. A method for adjusting an acoustically sealed transducer assembly having a buffer circuit comprising:
assembling the buffer circuit in an acoustically sealed housing, a portion of the buffer circuit accessible from outside the housing;
providing a desired response characteristic for the buffer circuit;
measuring an initial response characteristic of the buffer circuit;
comparing the desired response characteristic to the initial response characteristic;
determining an adjustment using the comparison, the adjustment for reducing a difference between the desired and initial response characteristics;
transmitting a signal to a selector circuit in the buffer circuit; and
tuning an adjustable filter coupled to the selector circuit, the adjustable filter for modifying the initial response characteristic.

12. The method of claim 11 further comprising:
removing the portion of the buffer circuit accessible from outside the housing, the portion used in transmitting the signal to the selector circuit.

13. The method of claim 12 wherein removing the portion of the buffer circuit further comprises removing the portion of the buffer circuit along one of a scoring and a line of weakness on a substrate carrying the buffer circuit.

14. The method of claim 11 wherein the tuning the adjustable filter further comprises activating a semiconductor device between an element of a ladder network and a ground connection.

15. The method of claim 11 wherein the tuning the adjustable filter further comprises biasing the selector circuit with a biasing component.

16. The method of claim 15 wherein the biasing component is a zener-zap diode.

17. The method of claim 15 wherein the biasing component is an electrically erasable programmable read-only memory (EEPROM).

18. The method of claim 15 wherein the biasing component is a polysilicon fuse.

19. The method of claim 15 wherein the biasing component is a laser trimmable hybrid resistor.

20. A transducer assembly having a transfer function of an acoustic energy to electrical energy comprising:
a housing comprising:
a first molded piece having an acoustic port;
a second molded piece coupled to the first molded piece;
a substrate having a first portion inside the housing and a second portion extending outside the housing; and
a circuit disposed on the substrate for receiving a signal corresponding to acoustic energy received at the acoustic port,
whereby the transfer function of the miniature transducer assembly can be altered by a signal injected at the second portion of the substrate.

21. The transducer assembly of claim 20 wherein the second portion of the substrate is removably attached to the first portion.

22. The transducer assembly of claim 20 wherein the circuit comprises a component for receiving the signal, the component operable to retain a programmed state after receiving the signal.

23. The transducer assembly of claim 22 wherein the component is coupled to one of a resistor ladder network and a decoder.

24. The transducer assembly of claim 20 wherein the component is one of a zener-zap diode, an electrically erasable programmable read only memory (EEPROM), a polysilicon fuse and a laser trimmable hybrid resistor.
